(19) United States
(12) Patent Application Publication
(10) Pub. No.: US 2014/0110806 A1
(43) Pub. Date: Apr. 24, 2014

(54) SOLID-STATE IMAGING DEVICE AND METHOD OF MANUFACTURING SOLID-STATE IMAGING DEVICE

(71) Applicant: KABUSHIKI KAISHA TOSHIBA, Tokyo (JP)

(72) Inventors: Ryota WATANABE, Oita (JP); Shinji UYA, Oita (JP)

(73) Assignee: Kabushiki Kaisha Toshiba, Tokyo (JP)

(21) Appl. No.: 13/867,309

(22) Filed: Apr. 22, 2013

(30) Foreign Application Priority Data
Oct. 23, 2012 (JP) 2012-234119

(51) Int. Cl. H01L 31/0232; H01L 31/18

(52) U.S. Cl. CPC H01L 31/0232; H01L 31/18
USPC 257/432; 438/69

(57) ABSTRACT

According to one embodiment, a solid-state imaging device includes a photoelectric conversion element, a fixed charge layer, a silicon nitride film, and a silicon oxide film. The photoelectric conversion element performs photoelectric conversion of converting incident light into the amount of charges corresponding to the amount of received light, and accumulates the charges. The fixed charge layer is formed on a light receiving surface side of the photoelectric conversion element, and holds negative fixed charges. The silicon nitride film is formed on a light receiving surface side of the fixed charge layer. The silicon oxide film is formed between the fixed charge layer and the silicon nitride film.

### CROSS-REFERENCE TO RELATED APPLICATIONS

This application is based upon and claims the benefit of priority from Japanese Patent Application No. 2012-234119, filed on Oct. 23, 2012; the entire contents of which are incorporated herein by reference.

### FIELD

Embodiments described herein relate generally to a solid-state imaging device and a method of manufacturing a solid-state imaging device.

### BACKGROUND

In the past, a solid-state imaging device includes a plurality of photoelectric conversion elements which are arranged in the form of a matrix to correspond to pixels of an imaging image, respectively. Each photoelectric conversion element performs photoelectric conversion of converting incident light into the amount of charges corresponding to the amount of received light, and accumulates the charges as information representing brightness of pixels.

In the solid-state imaging device, due to crystal defects in a light receiving surface of the photoelectric; conversion element, charges may be accumulated in the photoelectric conversion element regardless of the presence or absence of incident light. The charges may be detected as a dark current when an imaging image is output and shown in an imaging image as white flaws. Thus, in the solid-state imaging device, it is necessary to reduce the dark current.

### BRIEF DESCRIPTION OF THE DRAWINGS

FIG. 1 is an explanatory top view of a CMOS sensor according to an embodiment;

FIG. 2 is an explanatory cross-sectional view illustrating a part of a pixel unit according to an embodiment;

FIGS. 3A to 3D are explanatory cross-sectional views illustrating a process of manufacturing a CMOS sensor according to an embodiment;

FIGS. 4A to 4C are explanatory cross-sectional views illustrating a process of manufacturing a CMOS sensor according to an embodiment; and

FIGS. 5A to 5C are explanatory cross-sectional views illustrating a process of manufacturing a CMOS sensor according to an embodiment.

### DETAILED DESCRIPTION

In general, according to one embodiment, a solid-state imaging device includes a photoelectric conversion element, a fixed charge layer, a silicon nitride film, and a silicon oxide film. The photoelectric conversion element performs photoelectric conversion of converting incident light into the amount of charges corresponding to the amount of received light, and accumulates the charges. The fixed charge layer is formed on a light receiving surface side of the photoelectric conversion element, and holds negative fixed charges. The silicon nitride film is formed on a light receiving surface side of the fixed charge layer. The silicon oxide film is formed between the fixed charge layer and the silicon nitride film.

Exemplary embodiments of a solid-state imaging device and a method of manufacturing a solid-state imaging device will be explained below in detail with reference to the accompanying drawings. The present invention is not limited to the following embodiments.

In the present embodiment, the description will proceed using a so-called back-illuminated complementary metal oxide semiconductor (CMOS) image sensor in which an interconnection layer is formed on a surface side opposite to a subject light incidence surface of a photoelectric conversion element that performs photoelectric conversion on incident subject light as an example of a solid-state imaging device.

However, the solid-state imaging device according to the present embodiment is not limited to the back-illuminated CMOS image sensor and may be any image sensor such as a front-illuminated CMOS image sensor or a charge coupled device (CCD) image sensor.

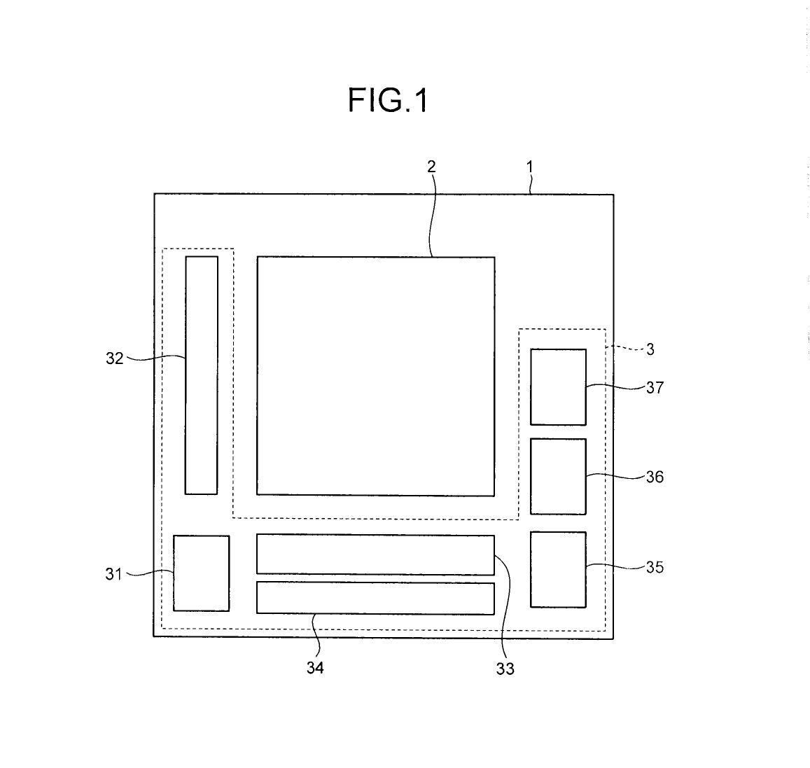

FIG. 1 is an explanatory top view illustrating a back-illuminated CMOS image sensor (hereinafter, referred to as a “CMOS sensor 1”) according to an embodiment. As illustrated in FIG. 1, the CMOS sensor 1 includes a pixel unit 2 and a logic unit 3.

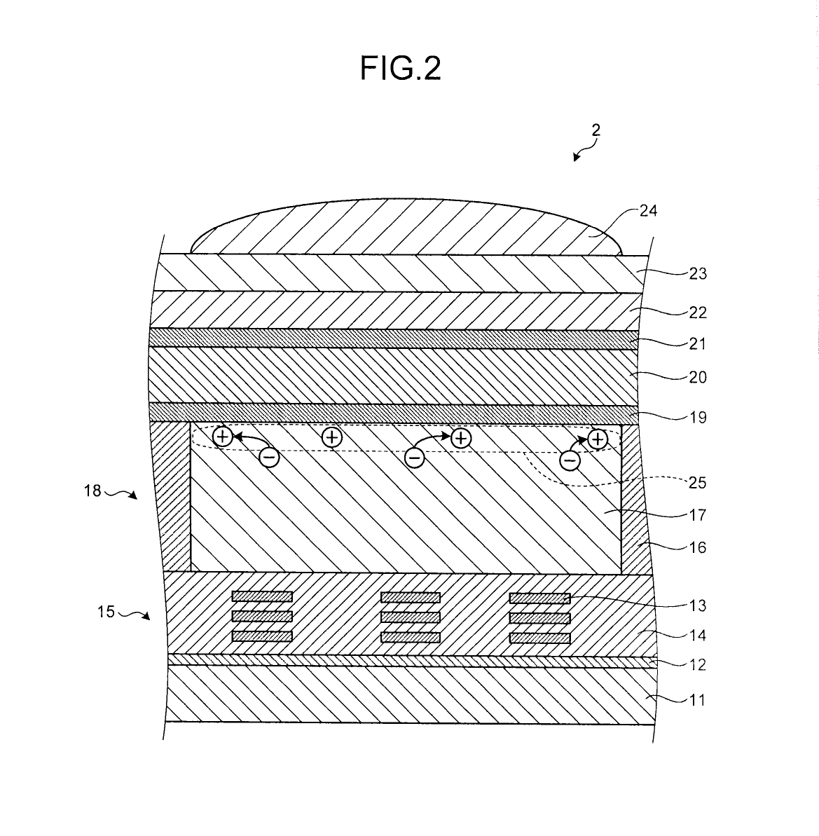

The pixel unit 2 includes a plurality of photoelectric conversion elements that are disposed in the form of a matrix. Each photoelectric conversion element performs photoelectric conversion of converting incident subject light into the amount of charges according to the amount of received light (intensity of received light), and accumulates the charges in a charge accumulation region. A configuration of the photoelectric conversion element will be described below with reference to FIG. 2.

The logic unit 3 includes a timing generator 31, a vertical selecting circuit 32, a sampling circuit 33, a horizontal selecting circuit 34, a gain control circuit 35, an analog/digital (A/D) converting circuit 36, an amplifying circuit 37, and the like.

The timing generator 31 is a processor that outputs a pulse signal used as a reference of an operation timing to the pixel unit 2, the vertical selecting circuit 32, the sampling circuit 33, the horizontal selecting circuit 34, the gain control circuit 35, the A/D converting circuit 36, the amplifying circuit 37, and the like.

The vertical selecting circuit 32 is a processor that sequentially selects a plurality of photoelectric conversion elements in units of rows to read charges out of the photoelectric conversion elements arranged in the form of a matrix. The vertical selecting circuit 32 outputs charges accumulated in the photoelectric conversion elements selected in units of rows from the photoelectric conversion elements to the sampling circuit 33 as a pixel signal representing brightness of each pixel.

The sampling circuit 33 is a processor that removes noise from the pixel signal input from each photoelectric conversion element selected in units of rows by the vertical selecting circuit 32 through correlated double sampling (CDS) and temporarily holds the sampled pixel signal.

The horizontal selecting circuit 34 is a processor that sequentially selects and reads the pixel signals held in the sampling circuit 33 in units of columns and outputs the pixel signals to the gain control circuit 35. The gain control circuit 35 is a processor that adjusts a gain of the pixel signal input from the horizontal selecting circuit 34 and outputs the pixel signal with the adjusted gain to the A/D converting circuit 36.

The A/D converting circuit 36 is a processor that converts the analog pixel signal input from the gain control circuit 35 into a digital pixel signal, and outputs the digital pixel signal to the amplifying circuit 37. The amplifying circuit 37 is a processor that amplifies the digital signal input from the A/D converting circuit 36 and outputs the amplified digital signal to a predetermined digital signal processor (DSP) (not illustrated).

As described above, the CMOS sensor 1 performs imaging such that a plurality of photoelectric conversion elements arranged in the pixel unit 2 perform photoelectric conversion of converting incident subject light to the amount of charges corresponding to the amount of received light and accumulate the charges, and the logic unit 3 reads the charges accumulated in the photoelectric conversion elements as the pixel signals.

In the CMOS sensor 1, when an interface state occurs due to a crystal defect or a contaminated material is attached to an end surface (hereinafter, referred to as a “light receiving surface”) at the side of the photoelectric conversion element to which incident light is incident, charges may be accumulated in a photoelectric conversion element that is not receiving incident light.

The charges may flow from the pixel unit 2 to the logic unit 3 as the dark current when the pixel signal is read by the logic unit 3 and be shown in the imaging image as white flaws. In this regard, in the CMOS sensor 1 according to an embodiment, the pixel unit 2 is configured to suppress the dark current. Next, a configuration of the pixel unit 2 according to an embodiment will be described with reference to FIG. 2.

FIG. 2 is an explanatory cross-sectional view illustrating a part of the pixel unit 2 according to an embodiment. FIG. 2 schematically illustrates a cross section of one pixel in the pixel unit 2.

As illustrated in FIG. 2, the pixel unit 2 includes an multi-layer interconnection layer 15 formed on a support substrate 11 with an adhesive layer 12 interposed therebetween, and a photoelectric conversion element 18. For example, the multi-layer interconnection layer 15 includes an interlayer insulating film 14 formed of a silicon (Si) oxide and a multi-layer interconnection 13 that is buried in the interlayer insulating film 14 and used to read negative charges that have been subjected to photoelectric conversion and transfer a driving signal or the like to each circuit element.

For example, the photoelectric conversion element 18 includes an N-type Si region 17 into which an N-type impurity such as phosphorous (P) is doped and a P-type Si region 16 into which a P-type impurity such as boron (B) is doped. Here, the P-type Si region 16 is formed to surround the N-type Si region 17 when viewed from the top.

The photoelectric conversion element 18 is a photodiode that is formed by a PN junction between the P-type Si region 16 and the N-type Si region 17. The photoelectric conversion element 18 performs photoelectric conversion of converting incident light incident from an end surface at the side opposite to the interface with the multi-layer interconnection layer 15 into the amount of negative charges corresponding to the amount of received light, and accumulates the charges in the N-type Si region 17.

The pixel unit 2 includes a first Si oxide film 19 that is formed on the light receiving surface of the photoelectric conversion element 18 at the thickness of 3 nm or less. Thus, in the pixel unit 2, a dangling bond occurring on the light receiving surface side end surface of the N-type Si region 17 can be reduced, and an increase in the interface state by the dangling bond can be suppressed.

Thus, according to the pixel unit 2, negative charges occurring due to the interface state regardless of the presence or absence of incident light can be prevented from being accumulated in the N-type Si region 17, and thus the dark current can be reduced.

In addition, the pixel unit 2 includes a fixed charge layer 20, in which the thickness for holding negative fixed charges is 10 nm or less, formed on the surface (light receiving surface) at the side of the first Si oxide film 19 on which incident light is incident. For example, the fixed charge layer 20 is formed of hafnium oxide (HfO).

A material of the fixed charge layer 20 is not limited to HfO, and may be made of any metallic oxide capable of holding negative fixed charges such as oxide of aluminum (Al), titanium (Ti), zirconium (Zr), or magnesium (Mg). Further, the fixed charge layer 20 may be made of a combination of materials selected from HfO, AlO, TiO, ZrO, and MgO. Further, the fixed charge layer 20 is formed by an atomic layer deposition (ALD) technique that is effective in forming a stable thin film.

As described above, the pixel unit 2 includes the fixed charge layer 20 for holding negative fixed charges, which is formed at the light receiving surface side of the N-type Si region 17 in the photoelectric conversion element 18 with the first Si oxide film 19 interposed therebetween. Thus, in the pixel unit 2, negative fixed charges held in the fixed charge layer 20 pulls positive charges (holes) present in the N-type Si region 17, and so a hole accumulating region 25 is formed near the light receiving surface of the N-type Si region 17.

The positive charges accumulated in the hole accumulating region 25 are re-combined with the negative charges caused by the interface state occurring near the light receiving surface of the N-type Si region 17, and thus the negative charges causing the dark current occurring regardless of the presence or absence of incident light can be reduced. Thus, according to the pixel unit 2, the dark current can be more effectively reduced.

In addition, the pixel unit 2 includes a second Si oxide film 21 having the thickness of 5 nm or less, a Si nitride film 22, a color filter 23, and a microlens 24, which are sequentially stacked on the surface (light receiving surface) at the side of the fixed charge layer 20 on which incident light is incident.

The microlens 24 is a plane-convex lens, and condenses incident light incident to the pixel unit 2 onto the photoelectric conversion element 18. For example, the color filter 23 allows incident light of any one f three primary colors of red, green, and blue to pass through. The Si nitride film 22 functions as an anti-reflection film that prevents reflection of incident light passing through the color filter 23.

Here, when the fixed charge layer 20 and the Si nitride film 22 are formed to come into contact with each other, nitrogen enters the fixed charge layer 20, and so the composition of the fixed charge layer 20 changes, and thus, the amount of generated fixed charges is reduced. As a result, the positive charge density of the hole accumulating region 25 on the N-type Si region 17 surface is reduced, and a dark current suppression effect is reduced.

Here, in order to reduce influence of nitrogen on the fixed charge layer 20, the fixed charge layer 20 may be thickly formed, but since the fixed charge layer 20 is formed by the ALD technique, a manufacturing load increases when a thick film is formed.

In this regard, a shielding film of physically separating the fixed charge layer 20 from the Si nitride film 22 is formed. It is effective to form a Si oxide film 21 that is stable in electric characteristic as this film. The Si oxide film 21 preferably has the thickness capable of sufficiently reducing influence of nitrogen on the fixed charge layer 20, for example, 5 nm or less.

The Si oxide film 21 is formed by the ALD technique that is effective in stably forming a thin film. As a result, since nitrogen is prevented from entering the fixed charge layer 20 and the film composition of the fixed charge layer 20 does not change, a decrease in the dark current suppression effect can be avoided.

Further, in the pixel unit 2, since the thickness of the first Si oxide film 19 is 3 nm or less and the thickness of the second Si oxide film 21 is 5 nm or less, reflection and infraction of incident light by the first Si oxide film 19 and the second Si oxide film 21 can be suppressed up to a negligible degree.

In addition, in the pixel unit 2, since the thickness of the fixed charge layer 20 is 10 nm or less, reflection and infraction of incident light by the fixed charge layer 20 can be suppressed up to a negligible degree while holding negative charges in the fixed charge layer 20 by the necessary amount.

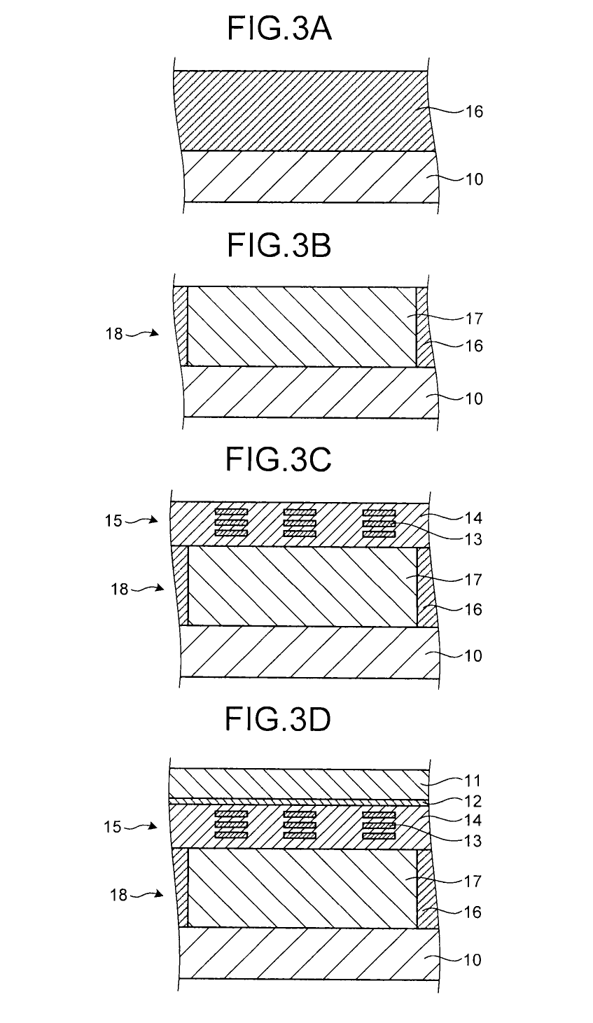

Next, a method of manufacturing the CMOS sensor 1 according to an embodiment will be described with reference to FIGS. 3 to 5. A method of manufacturing the logic unit 3 in the CMOS sensor 1 is the same as in the general CMOS sensor according to the related art. Thus, the following description will proceeds in connection with a method of manufacturing the pixel unit 2 in the CMOS sensor 1, and a description of a method of manufacturing the logic unit 3 will not be made.

FIGS. 3A to 5C are explanatory cross-sectional views illustrating a method of manufacturing the CMOS sensor 1 according to an embodiment. FIGS. 3A to 5C schematically illustrating a manufacturing process of one pixel in the pixel unit 2.

As illustrated in FIG. 3A, when the CMOS sensor 1 is manufactured, a P-type Si region 16 is formed on a semiconductor substrate 10 such as a Si wafer. At this time, for example, the P-type Si region 16 is formed such that a Si layer into which a P-type impurity such as boron (B) is doped is epitaxially grown from the semiconductor substrate 10. The P-type Si region 16 may be formed such that a P-type impurity is ion-doped into a Si wafer, and then an annealing process is performed.

Next, as illustrated in FIG. 3B, an opening is formed on a predetermined region of the P-type Si region 16 from the top surface toward the semiconductor substrate 10, and thereafter a N-type Si region 17 is formed in the opening portion. At this time, for example, the N-type Si region 17 is formed such that a Si layer into which an N-type impurity such as phosphorous (P) is doped is epitaxially grown in the opening portion.

The N-type Si region 17 may be formed such that an N-type impurity is ion-doped from the top surface side of the P-type Si region 16 to the inside of the P-type Si region 16, and then an annealing process is performed. A plurality of N-type Si regions 17 are arranged in the form of a matrix when viewed from the top.

As the N-type Si region 17 is buried in the P-type Si region 16 as described above, a PN junction is formed, and thus a photoelectric conversion element 18 that is a photodiode is formed. Here, the N-type Si region 17 serves as a charge accumulation region in which negative charges that has been subjected to photoelectric conversion are accumulated, and the joint surface with the semiconductor substrate 10 is exposed later to function as the light receiving surface of incident light.

Next, as illustrated in FIG. 3C, a multi-layer interconnection layer 15 is formed on the top surface of the photoelectric conversion element 18. At this time, for example, the multi-layer interconnection layer 15 is formed by repeating a process of forming an interlayer insulating film 14 such as a Si oxide film, a process of forming a predetermined interconnection pattern on the interlayer insulating film 14, and a process of burying copper (Cu) or the like in the interconnection pattern and forming a multi-layer interconnection 13. Thereafter, as illustrated in FIG. 3D, the top surface of the multi-layer interconnection layer 15 is applied with an adhesive to form an adhesive layer 12, and a support substrate 11 such as a Si wafer adheres to the top surface of the adhesive layer 12.

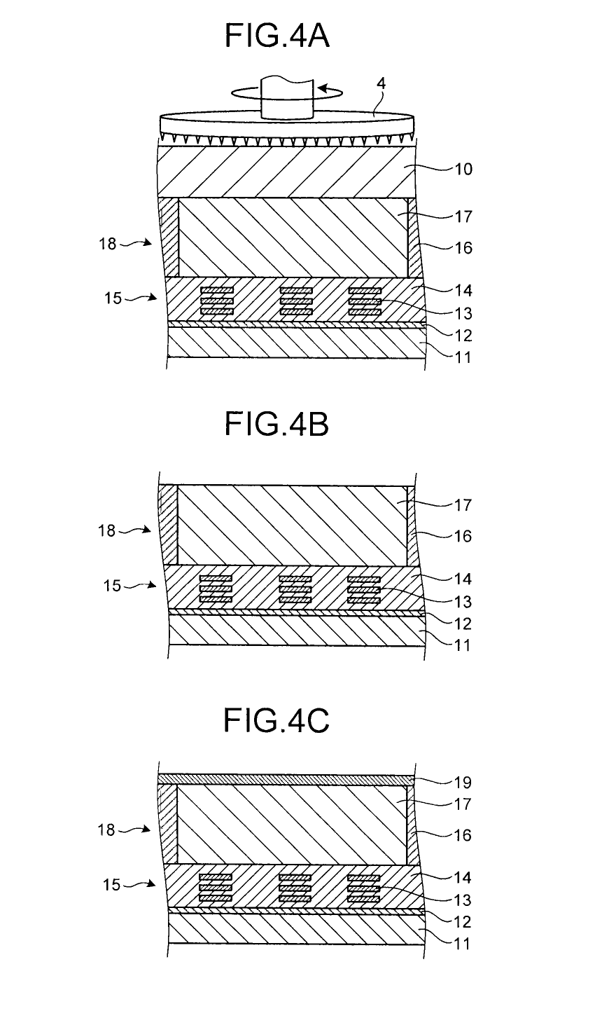

Next, as illustrated in FIG. 4A, the structure illustrated in FIG. 3D is reversed up and down, the back surface side (here, the top surface side) of the semiconductor substrate 10 is polished by a polishing apparatus 4 such as a grinder until the thickness of the semiconductor substrate 10 is reduced to a predetermined thickness.

Thereafter, for example, the back surface of the semiconductor substrate 10 is further polished by chemical mechanical polishing (CMP), and thus the back surface (here, the top surface) of the N-type Si region 17 is exposed as illustrated in FIG. 4B. At this time, a dangling bond occurs on the top surface that is the polished surface of the N-type Si region 17, and thus an interface state occurs.

Here, as described above, the N-type Si region 17 is a charge accumulation region in which negative charges that have been subjected to photoelectric conversion are accumulated, and the exposed top surface serves as the light receiving surface of the photoelectric conversion element 18. Then, when the interface state occurs on the light receiving surface of the photoelectric conversion element 18, negative charges generated due to the interface state regardless of the presence or absence of incident light are accumulated in the N-type Si region 17, leading to the dark current.

In this regard, in the method of manufacturing the CMOS sensor 1 according to an embodiment, as illustrated in FIG. 4C, a first Si oxide film 19 having the thickness of 3 nm or less is formed on the light receiving surface of the photoelectric conversion element 18.

Here, the first Si oxide film 19 is formed using the ALD technique. This is appropriate to form the Si oxide film 19 due to the features that since a film can be formed at the temperature of about 400° C., an elution problem can be avoided even when copper (Cu) is used for the multi-layer interconnection 13 already formed at the time of the forming of the Si oxide film 19, a Si interface can be formed more stably than in other low-temperature film forming techniques such as a plasma chemical vapor deposition (CVD) technique, and film thickness controllability at the time of forming of a thin film is excellent.

As the first Si oxide film 19 is formed on the light receiving surface of the photoelectric conversion element 18 as described above, the interface state is suppressed from being formed on the top surface of the N-type Si region 17, and thus the dark current can be reduced. In addition, the first Si oxide film 19 has the thickness of 3 nm or less, reflection and infraction of incident light can be suppressed up to a negligible degree.

Here, the description has been made in connection with the example in which the first Si oxide film 19 is formed on the top surface of the N-type Si region 17 and the top surface of the P-type Si region 16, but generation of negative charges causing the dark current can be suppressed when the first Si oxide film 19 is formed on at least the top surface of the N-type Si region 17.

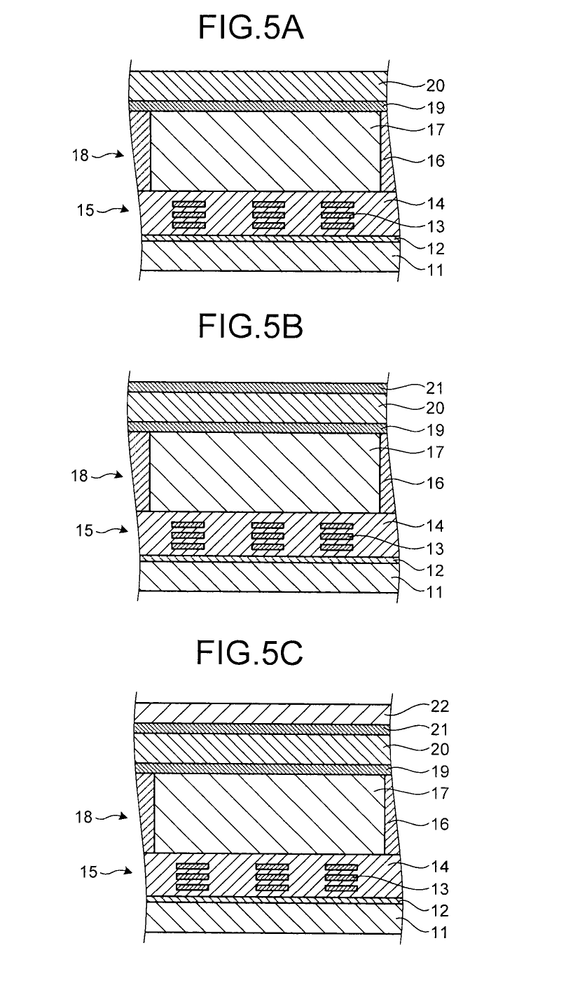

Next, as illustrated in FIG. 5A, a fixed charge layer 20 that holds negative fixed charges is formed on the top surface of the first Si oxide film 19. For example, the fixed charge layer 20 is formed of an HfO film having the thickness of 10 nm or less.

Here, the fixed charge layer 20 is formed using the ALD technique. This is appropriate to form the fixed charge layer 20 due to the features that since a film can be formed at the temperature of 400° C. or less, an elution problem can be avoided even when copper (Cu) is used for the multi-layer interconnection 13 already formed at the time of the forming of the Si oxide film 19, and film thickness controllability at the time of forming of a thin film is excellent.

In addition, as at least a part of the HfO film is crystallized according to a processing temperature at the time of film forming or a processing temperature of a subsequent forming process, negative fixed charges are charged and pulled to the crystallized HfO film, and thus the hole accumulating region 25 is formed on the light irradiation interface side of the N-type Si region 17. As a result, electrons, which are generated by a crystal defect or a heavy metal element, present near the interface while causing the dark current, are re-combined with holes. Thus, according to the CMOS sensor 1, the dark current can be further reduced.

Here, the description has been made in connection with the example in which the material of the fixed charge layer 20 is HfO, but the material of the fixed charge layer 20 may be a material containing one or more of Hf, Ti, Al, Zr, and Mg.

Thereafter, a second Si oxide film 21 is formed on the surface (light receiving surface) of the fixed charge layer 20 on which incident light is incident as illustrated in FIG. 5B and then a Si nitride film 22 serving as an anti-reflection film is formed on the surface (light receiving surface) of the second Si oxide film 21 on which incident light is incident as illustrated FIG. 5C.

At this time, the second Si oxide film 21 is formed by the ALD technique, similarly to the first Si oxide film 19. The Si nitride film 22 is formed by a general CVD technique. HfO used for the fixed charge layer 20 has a high-refractive index film, and thus even a single HfO film can undertake the function of the anti-reflection film. However, in order to stably generate fixed charges, the ALD technique needs to be used for forming of a film, but since it takes a long time to form a film, and forming of a thick film increases a burden on productivity. In this regard, even when the fixed charge layer 20 is used, the anti-reflection film is formed of the Si nitride film 22 that can be formed by the CVD technique, and thus a burden on productivity can be reduced.

As described above, in the method of manufacturing the CMOS sensor 1 according to an embodiment, the second Si oxide film 21 is formed between the fixed charge layer 20 and the Si nitride film 22, and thus a change in the composition of the fixed charge layer 20 is suppressed, and the stable fixed charge layer 20 can be formed. In addition, the anti-reflection layer is formed such that the Si nitride film is formed using the CVD technique, and a load of productivity can be reduced.

As a result, in the method of manufacturing the CMOS sensor 1, a decrease in the amount of positive charges accumulated in the hole accumulating region 25 (see FIG. 2) of the N-type Si region 17 can be suppressed, and thus the CMOS sensor 1 in which the dark current is greatly reduced can be manufactured.

In addition, the first Si oxide film 19 and the second Si oxide film 21 have the same thickness to satisfy the same condition, and thus operation efficiency of a device at the time of forming of the films increases, and a load of productivity can be further reduced.

Thereafter, in the method of manufacturing the CMOS sensor 1, the color filter 23 and the microlens 24 are sequentially formed on the top surface of the Si nitride film 22, so that CMOS sensor 1 including the pixel unit 2 illustrated in FIG. 2 is manufactured.

Further, the present embodiment has been described in connection with the example in which the first Si oxide film 19, the fixed charge layer 20, and the second Si oxide film 21 are all formed using the ALD technique, but at least one of the first Si oxide film 19, the fixed charge layer 20, and the second Si oxide film 21 may be formed by the ALD technique.

As described above, a solid-state imaging device according to an embodiment includes a photoelectric conversion element, a fixed charge layer, and a silicon nitride film, and a silicon oxide film. The photoelectric conversion element performs photoelectric conversion of converting incident light into the amount of charges corresponding to the amount of received light, and accumulates the charges. The fixed charge layer is formed on a light receiving surface side of the photoelectric conversion element, and holds negative fixed charges. The silicon nitride film is formed on a light receiving surface side of the fixed charge layer. The silicon oxide film is formed between the fixed charge layer and the silicon nitride film.

According to the solid-state imaging device, the silicon oxide film formed between the fixed charge layer and the silicon nitride film prevents negative charges in the fixed charge layer from being re-combined with positive charges in the silicon nitride film and decreasing, and thus the dark current can be greatly reduced.

Further, the solid-state imaging device according to an embodiment further includes the silicon oxide film formed on the light receiving surface of the photoelectric conversion element. Thus, the solid-state imaging device according to an embodiment can be suppress an increase in the interface state occurring on the light receiving surface of the photoelectric conversion element, and thus, the dark current can be further reduced.

In addition, the silicon oxide film and the fixed charge layer according to an embodiment are formed using the ALD technique. According to the ALD technique, for example, the silicon oxide film and the fixed charge layer can be formed at the processing temperature lower than the melting point of metal used for the multi-layer interconnection of the solid-state imaging device. Thus, the solid-state imaging device according to an embodiment can prevent the forming of the silicon oxide film and the fixed charge layer from adversely affecting the multi-layer interconnection.

Furthermore, the silicon oxide film formed between the fixed charge layer and the silicon nitride film according to an embodiment has the thickness of 5 nm or less, and the silicon oxide film formed on the light receiving surface of the photoelectric conversion element has the thickness of 3 nm or less. According to the silicon oxide film, reflection and infraction of incident light incident to the photoelectric conversion element can be suppressed up to a negligible degree.

Moreover, the fixed charge layer according to an embodiment has the thickness of 10 nm or less. This thickness is a minimum thickness necessary to generate negative fixed charges for reducing the dark current, and the anti-reflection film is formed of a Si nitride film that can be formed using a CVD technique having a low productivity load.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a photoelectric conversion element that performs photoelectric conversion of converting incident light into an amount of charges corresponding to an amount of received light and accumulates the charges;
a fixed charge layer that is formed on a light receiving surface side of the photoelectric conversion element and holds negative fixed charges;
a silicon nitride film that is formed on a light receiving surface side of the fixed charge layer; and
a silicon oxide film that is formed between the fixed charge layer and the silicon nitride film.

2. The solid-state imaging device according to claim 1, further comprising a silicon oxide film formed on a light receiving surface of the photoelectric conversion element.

3. The solid-state imaging device according to claim 1,
wherein the silicon oxide film and the fixed charge layer are formed using an atomic layer deposition (ALD) technique.

4. The solid-state imaging device according to claim 1,
wherein the silicon oxide film formed between the fixed charge layer and the silicon nitride film has a thickness of 5 nm or less.

5. The solid-state imaging device according to claim 1,
wherein the fixed charge layer has a thickness of 10 nm or less.

6. The solid-state imaging device according to claim 2,
wherein the silicon oxide film formed on the light receiving surface of the photoelectric conversion element has a thickness of 3 nm or less.

7. The solid-state imaging device according to claim 2,
wherein the silicon oxide film formed between the fixed charge layer and the silicon nitride film is equal in thickness to the silicon oxide film formed on the light receiving surface of the photoelectric conversion element.

8. The solid-state imaging device according to claim 1,
wherein the fixed charge layer has a crystallized portion.

9. The solid-state imaging device according to claim 1,
wherein the silicon nitride film is formed using a chemical vapor deposition (CVD) technique.

10. The solid-state imaging device according to claim 1,
wherein the solid-state imaging device is a back-illuminated image sensor, and the fixed charge layer and the silicon oxide film are formed at a film forming temperature lower than a melting point of an interconnection included in the back-illuminated image sensor.

11. A method of manufacturing a solid-state imaging device, comprising:
forming a photoelectric conversion element that performs photoelectric conversion of converting incident light into an amount of charges corresponding to an amount of received light and accumulates the charges;
forming a fixed charge layer that holds negative fixed charges on a light receiving surface side of the photoelectric conversion element;
forming a silicon oxide film on a light receiving surface side of the fixed charge layer; and
forming a silicon nitride film on a light receiving surface side of the silicon oxide film.

12. The method according to claim 11, further comprising
forming a silicon oxide film on a light receiving surface of the photoelectric conversion element.

13. The method according to claim 11,
wherein the silicon oxide film and the fixed charge layer are formed using an atomic layer deposition (ALD) technique.

14. The method according to claim 11,
wherein the silicon oxide film formed between the fixed charge layer and the silicon nitride film has a thickness of 5 nm or less.

15. The method according to claim 11,
wherein the fixed charge layer has a thickness of 10 nm or less.

16. The method according to claim 12,
wherein the silicon oxide film formed on the light receiving surface of the photoelectric conversion element has a thickness of 3 nm or less.

17. The method according to claim 12,
wherein the silicon oxide film formed between the fixed charge layer and the silicon nitride film is equal in thickness to the silicon oxide film formed on the light receiving surface of the photoelectric conversion element.

18. The method according to claim 11,
wherein a part of the fixed charge layer is crystallized.

19. The method according to claim 11,
wherein the silicon nitride film is formed using a chemical vapor deposition (CVD) technique.

20. The method according to claim 11,
wherein the solid-state imaging device is a back-illuminated image sensor, and the fixed charge layer and the silicon oxide film are formed at a film forming temperature lower than a melting point of an interconnection included in the back-illuminated image sensor.
